(19) United States
(12) Patent Application Publication
(10) Pub. No.: US 2009/0032794 A1
(43) Pub. Date: Feb. 5, 2009

(54) PHASE CHANGE MEMORY DEVICE AND FABRICATION METHOD THEREOF

(75) Inventor: Tsai-Chu Hsiao, Taoyuan County (TW)

Correspondence Address: QUINTERO LAW OFFICE, PC, 2210 MAIN STREET, SUITE 200, SANTA MONICA, CA, 90405, US

(73) Assignees: INDUSTRIAL TECHNOLOGY RESEARCH INSTITUTE, HSINCHU (TW); POWERCHIP SEMICONDUCTOR CORP., HSIN-CHU (TW); NANYA TECHNOLOGY CORPORATION, TAOYUAN (TW); PROMOS TECHNOLOGIES INC., HSINCHU (TW); WINBOND ELECTRONICS CORP., HSINCHU (TW)

(21) Appl. No.: 11/965,569

(22) Filed: Dec. 27, 2007

(30) Foreign Application Priority Data
Aug. 1, 2007 (TW) TW96128178

(51) Int. Cl. H01L 29/06; H01L 21/425

(52) U.S. Cl. 257/4; 438/530; 257/E29.006; 257/E21.473

(57) ABSTRACT

A phase change memory device is disclosed. A first dielectric layer having a sidewall is provided. A bottom electrode is adjacent to the sidewall of the first dielectric layer, wherein the bottom electrode comprises a seed layer and a conductive layer. A second dielectric layer is adjacent to a side of the bottom electrode opposite the sidewall of the first dielectric layer. A top electrode couples the bottom electrode through a phase change layer.

### BACKGROUND OF THE INVENTION

1. Field of the Invention

The invention relates to a memory device and more particularly, relates to a phase change memory device and fabrication method thereof.

2. Description of the Related Art

Phase change memory devices have many advantages, such as faster speeds, lower power consumption, large capacity, greater endurance, better processing integrity and lower cost. Phase change memory devices can thus be used as stand-alone or embedded memory devices with high degree of integrity. Due to the described advantages and others, phase change memory device may substitute in place of volatile memory devices, such as SRAM and DRAM, or non-volatile memory devices, such as flash memory devices for respective applications.

Phase change memory devices write, read or erase according to different resistances of a phase change material between a crystal state and a non-crystal state. For example, a relatively high current and short pulse, such as 1 mA with 50 ns, is applied to a phase change layer to raise the temperature of the active volume above the melting temperature of the materials and follows by a quench immediately after the end of the pulse for the phase change layer to change from a crystal state to a non-crystal state. Because the non-crystal state phase change layer has higher resistance, about 10⁵ ohm, the phase change memory device presents a smaller current when applied with a voltage to read. When erasing, the phase change layer is applied with a low current, about 0.2 mA, for a longer duration, about 100 ns, to raise the temperature of the active volume above the recrystalization temperature but under the melting temperature. The active volume changes from a non-crystal state back to a crystal state reversibly. Since the crystal state phase change layer has lower resistance, such as 10³˜10⁴ ohm, the phase change memory device presents a higher current when applied with a voltage to read. The phase change memory device operates in accordance with the above described.

Currently, one object in developing phase change memory devices is to reduce operating voltage. One method is to form a structure with a contact area between a phase change layer and an electrode not limited by lithography. Referring to FIG. 1, a phase change memory device 100 using a sidewall layer as a bottom electrode 104 is disclosed. An insulating layer 106 is formed on a substrate 102. A bottom electrode 104 is formed on a sidewall of the insulating layer 106. A phase change layer 108 and a top electrode 110 are sequentially formed on the bottom electrode 104 and the insulating layer 106. The phase change memory device 100, however, has higher parasitic resistance, thus affecting voltage drop thereof.

Typically, the bottom electrode 104 of the phase change memory device 100 in FIG. 1 includes Ta or TaN, in which TaN is formed by introducing nitrogen into a chamber when depositing a Ta film. In order to decrease resistance of the bottom electrode 104, nitrogen concentration is required to be reduced. Referring to FIG. 2, when nitrogen concentration in the chamber is reduced, TaN phase changes from body centered cubic phase (c-TaN) to a-Ta₂N phase, and then to α phase [α-Ta(N)]. As shown in FIG. 2, the resistance of α-Ta(N), however, still maintains at about 200 μΩ-cm, even when nitrogen concentration in the chamber is reduced to a low level. Consequently, resistance of the bottom electrode 104 comprising TaN is not low enough.

Voltage drop of a phase change memory unit is generated by current drivers, cell selectors, conductive lines and cells. In order to spare enough voltage for the active device such as transistor, voltage drop of a phase change memory unit should be reduced. Therefore, a phase change memory cell with low voltage drop is needed.

### BRIEF SUMMARY OF INVENTION

A detailed description is given in the following embodiments with reference to the accompanying drawings. These and other problems are generally solved or circumvented, and technical advantages are generally achieved, by the invention. Specifically, an embodiment of the invention provides a phase change memory device having a contact area between a phase change layer and a bottom electrode not limited by lithography, and having small parasitic resistance to increase design flexibility.

An embodiment of the invention discloses a phase change memory device. A first dielectric layer having a sidewall is provided. A bottom electrode is adjacent to the sidewall of the first dielectric layer, wherein the bottom electrode comprises a seed layer and a conductive layer. A second dielectric layer is adjacent to a side of the bottom electrode opposite the sidewall of the first dielectric layer. A top electrode couples the bottom electrode through a phase change layer.

Another embodiment of the invention discloses a method for forming a phase change memory device. A first dielectric layer is formed on a substrate. The first dielectric layer is patterned to form an opening. A seed layer is conformally deposited on the first dielectric layer and into the opening. A conductive layer is conformally deposited on the seed layer. A second dielectric layer is blanketly deposited on the conductive layer. The second dielectric layer is recessed till the first dielectric layer, the seed layer and the conductive layer are exposed, wherein both the seed layer and the conductive layer are used as a bottom electrode of the phase change memory device. A phase change layer is formed on the second dielectric layer, the seed layer and the conductive layer. A top electrode is formed on the phase change layer.

### BRIEF DESCRIPTION OF DRAWINGS

The invention can be more fully understood by reading the subsequent detailed description and examples with references made to the accompanying drawings, wherein:

FIG. 1 shows a cross section of a conventional phase change memory device.

FIG. 2 shows a chart, illustrating resistance versus nitrogen flow of a TaN bottom electrode of a conventional phase change memory device.

FIGS. 3A˜3G show intermediate cross sections of a phase change memory device of an embodiment of the invention.

FIG. 4 shows a chart, illustrating resistance versus nitrogen flow of a bottom electrode comprising stacked Ti and TaN layers of an example of an embodiment of the invention.

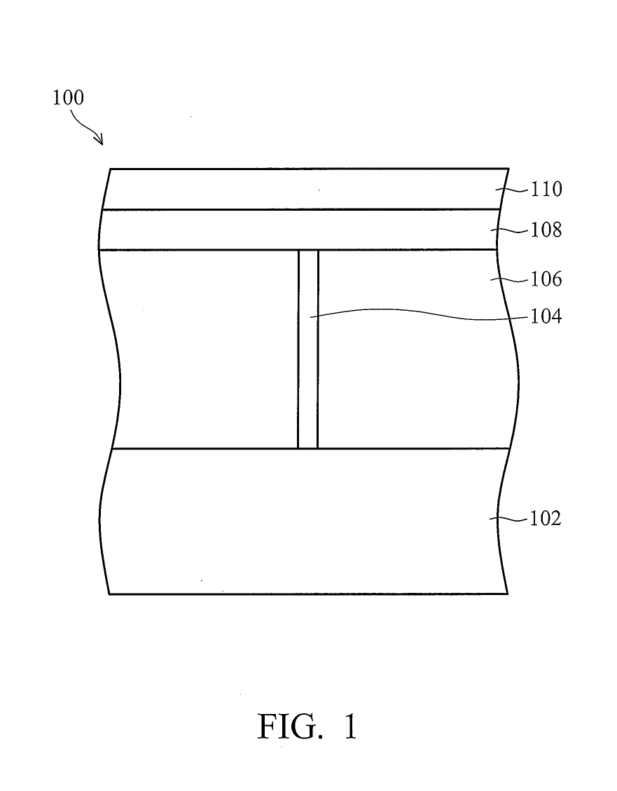

### DETAILED DESCRIPTION OF INVENTION

The following description is of the contemplated mode of carrying out the invention. This description is made for the purpose of illustrating the general principles of the invention and should not be taken in a limiting sense. The scope of the invention is best determined by reference to the appended claims. Embodiments of the invention, which provide a phase change memory device, will be described in greater detail by referring to the drawings that accompany the invention. It is noted that in the accompanying drawings, like and/or corresponding elements are referred to by like reference numerals.

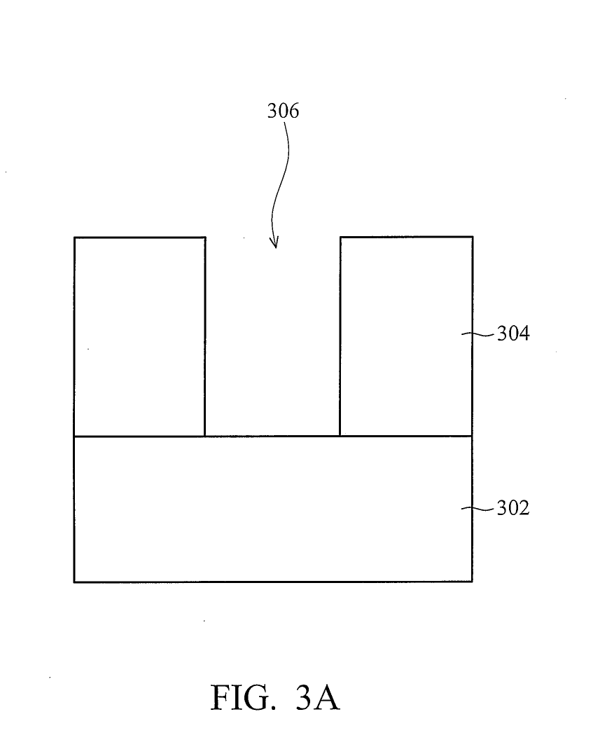

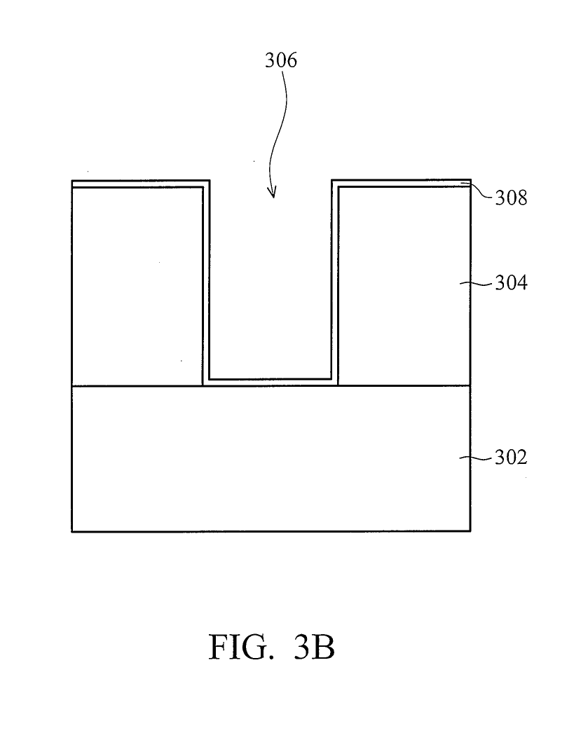

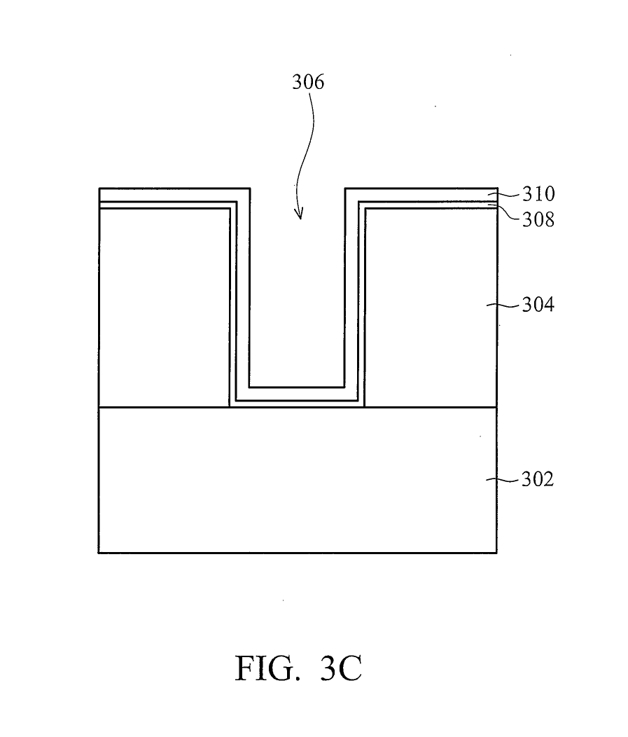

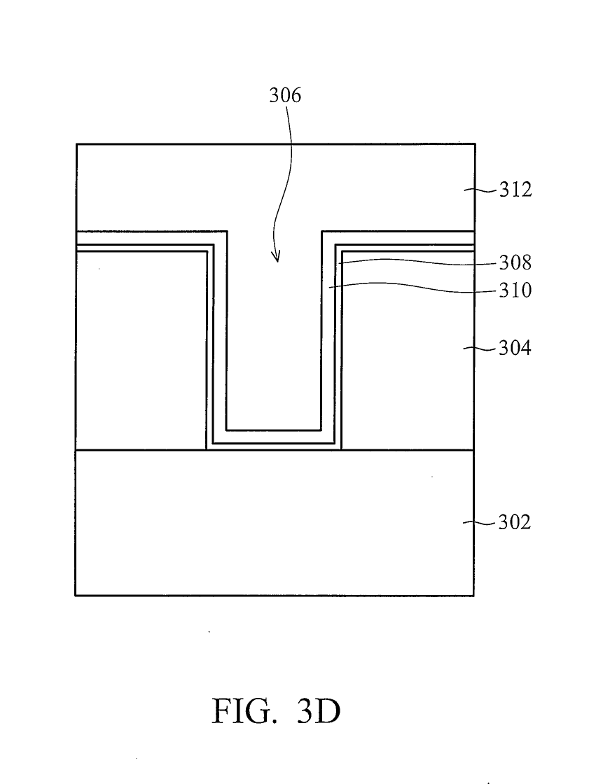

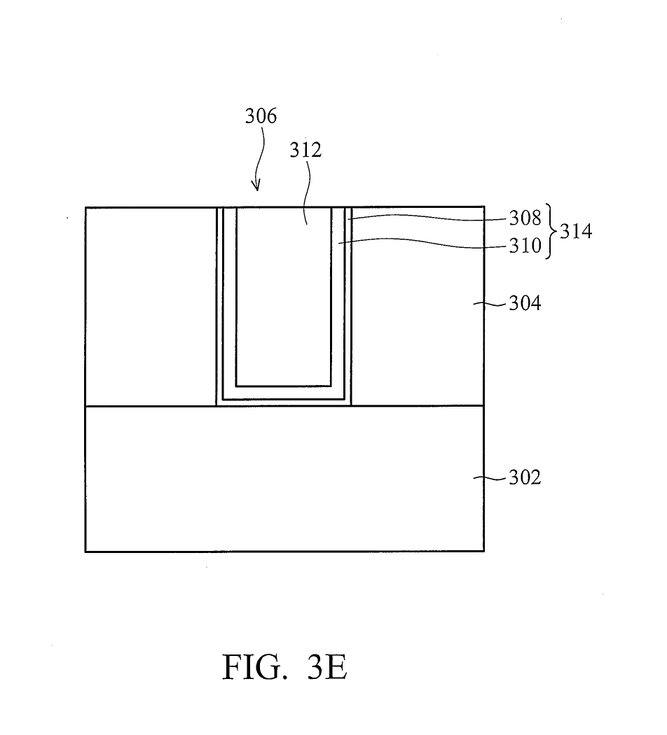

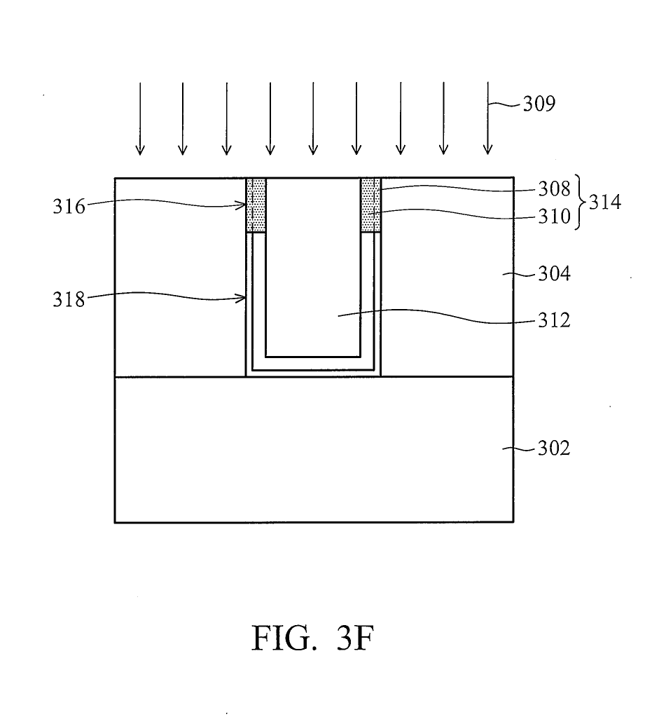

FIGS. 3A˜3G show intermediate cross sections of a phase change memory device of an embodiment of the invention. Referring to FIG. 3A, a semiconductor substrate 302, such as silicon, is provided. The substrate 302 is shown as a plane substrate for simplification, but the substrate 302 can comprise semiconductor devices, such as MOS transistors, resistors and/or logic devices. In the description, “substrate” comprises devices and layers formed thereon, and “substrate surface” comprises an exposed top layer on a semiconductor wafer, such as a silicon wafer surface, an insulating layer, and a conductive line.

Next, a first dielectric layer 304 is formed on the substrate 302 by, for example, chemical vapor deposition CVD. The first dielectric layer 304 can comprise silicon oxide, silicon nitride, silicon oxynitride or low k dielectric materials.

Thereafter, the first dielectric layer 304 is patterned to form an opening 306 by, for example, lithography and etching. In an embodiment, the opening 306 is circular or retangular-shaped, but the invention is not limited thereto. The opening 306 can be other shapes.

Referring to FIG. 3B, a seed layer 308 is conformally formed on the first dielectric layer 304 and into the opening 306. Specifically, the seed layer 308 covers sidewalls of the opening 306 in the first dielectric layer 304. In an embodiment of the invention, the seed layer 308 includes Ti, and is about 1˜10 nm thick.

Referring to FIG. 3C, a conductive layer 310 is conformally formed on the seed layer 308. In an embodiment of the invention, the conductive layer 310 comprises Ta, or TaN containing less nitrogen, and is about 10˜100 nm thick. The Ta layer can be formed by physical vapor deposition PVD. The TaN layer can be formed by introducing a small amount of nitrogen into a chamber when depositing the Ta film.

Referring to FIG. 3D, a second dielectric layer 312 is formed on the conductive layer 310 by, for example, chemical vapor deposition CVD, filling the remaining portion of the opening 306. The second dielectric layer 312 can comprise silicon oxide, silicon nitride, silicon oxynitride or low k dielectric materials.

Referring to FIG. 3E, the second dielectric layer 312 is recessed by, for example, chemical mechanical polishing CMP till the first dielectric layer 304, the seed layer 308 and the conductive layer 310 are exposed. In the embodiment, both the seed layer 308 and the conductive layer 310 are used as a bottom electrode 314 of the phase change memory device. Next, referring to FIG. 3F, the bottom electrode 314 is doped by a doping process 309, such as an ion implantation or thermal diffuse process. Thus, the bottom electrode 314 includes a barrier region 316 and a conducting region 318. The barrier region 316 has higher resistance due to higher doping concentration, and the conducting region 318 has lower resistance due to undoped or lower doping concentration. In an embodiment of the invention, the bottom electrode 314 is doped with nitrogen by an ion implantation or thermal diffuse process, forming a barrier region 316 and a conducting region 318. The barrier region 316 is adjacent to a phase change layer formed thereafter, and the conducting region 318 is away from the phase change layer.

In an embodiment, after the doping step 309, the barrier region 316 of the bottom electrode 314 includes stacked TiN layer and TaN layer, and the conducting region 318 of the bottom electrode 314 includes stacked Ti layer and Ta layer. In another embodiment of the invention, ratio of Ta: N in the barrier region 316 is about 1-x: x (x=0˜0.7), and resistance of the barrier region 316 is more than twice that of the conducting region 318.

Referring to FIG. 3G, a phase change layer 320 is formed on the first dielectric layer 304, the second dielectric layer 312, the seed layer 308 and the conductive layer 310. A top electrode 322 is then formed on the phase change layer 320.

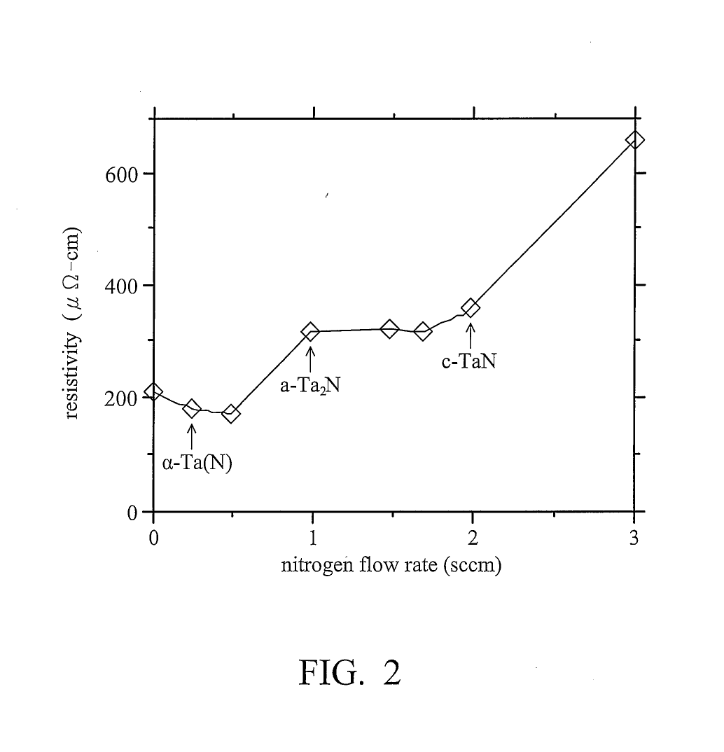

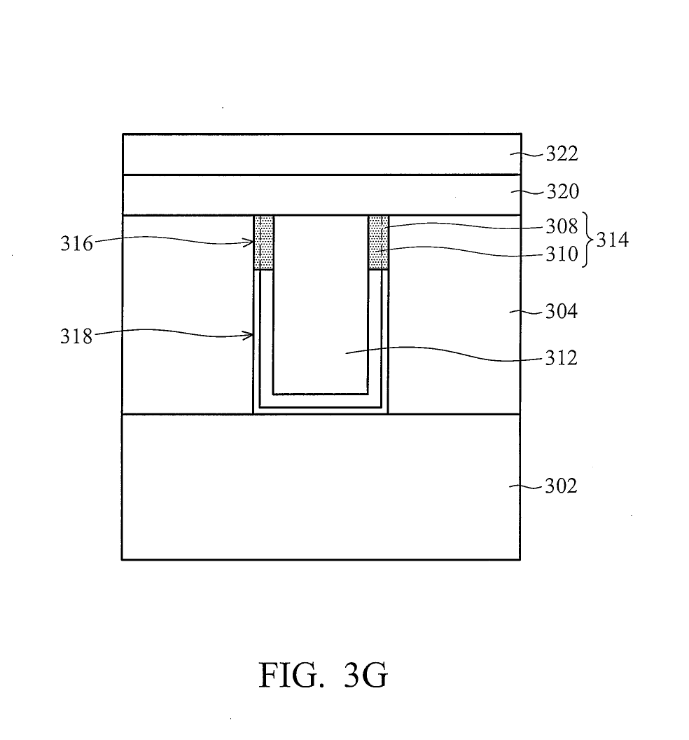

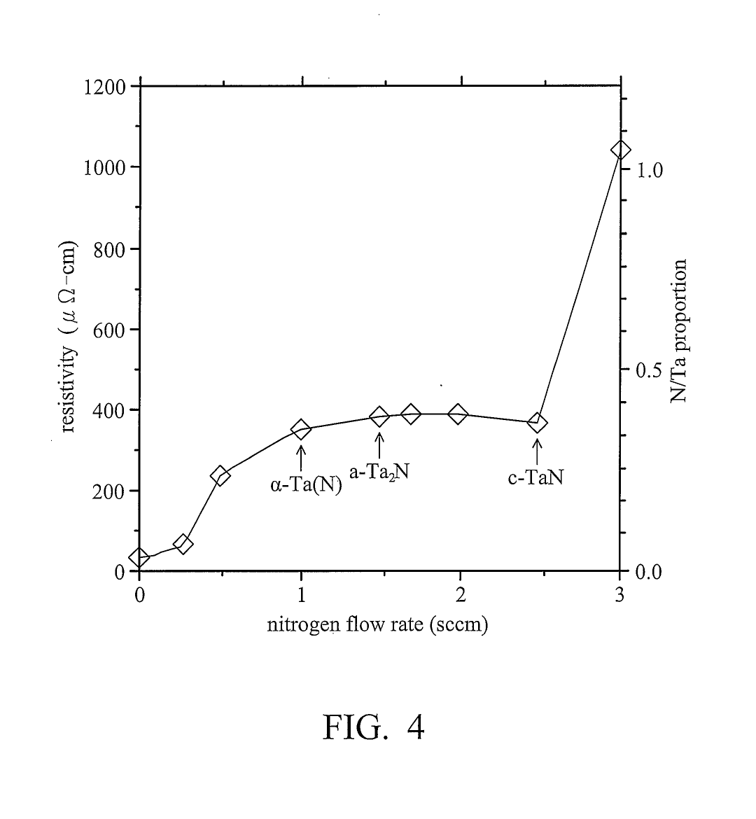

FIG. 4 shows a chart, illustrating resistance versus nitrogen flow of a bottom electrode comprising stacked Ti and TaN layers of an example of an embodiment of the invention. Referring to FIG. 4, resistance of the embodiment in FIG. 3G is very small when nitrogen gas first flows in at about zero, and presents high enough resistance when nitrogen gas flow is increased to about 3 sccm. For example, the conducting region 318 of the bottom electrode 314 can have resistance substantially less then 200 μΩ-cm (can be further less than about 100 μΩ-cm), and the barrier region 316 of the bottom electrode 314 can have resistance substantially more then 600 μΩ-cm. In contrast, in the prior art in FIG. 2 resistance is maintained at about 200 μΩ-cm when nitrogen gas flow first flows in at about zero. Consequently, the bottom electrode 314 of the embodiment of the invention includes a conducting region 318 with low resistance to reduce parasitic resistance and voltage drop, and a barrier region 316 with high enough resistance to generate phase change at an interface between the bottom electrode 314 and the phase change layer 320 when heated.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A phase change memory device, comprising:
a first dielectric layer having a sidewall;
a bottom electrode adjacent to the sidewall of the first dielectric layer, wherein the bottom electrode comprises a seed layer and a conductive layer;
a second dielectric layer adjacent to a side of the bottom electrode opposite to the sidewall of the first dielectric layer; and
a top electrode coupling the bottom electrode through a phase change layer.

2. The phase change memory device as claimed in claim 1, wherein the seed layer comprises Ti.

3. The phase change memory device as claimed in claim 1, wherein the conductive layer comprises Ta or TaN.

4. The phase change memory device as claimed in claim 1, wherein the bottom electrode includes a barrier region and a conducting region, the barrier region is closer to the phase change layer than the conducting region, and resistance of the barrier region is higher than that of the conducting region.

5. The phase change memory device as claimed in claim 4, wherein resistance of the barrier region is more than twice that of the conducting region.

6. The phase change memory device as claimed in claim 4, wherein the barrier region of the bottom electrode comprises a TiN layer and a TaN layer, and the conducting region of the bottom electrode comprises a Ti layer and a Ta layer.

7. The phase change memory device as claimed in claim 4, wherein resistance of the conducting region of the bottom electrode is substantially less than 200 ∥Ω-cm.

8. The phase change memory device as claimed in claim 4, wherein resistance of the barrier region of the bottom electrode is substantially more than 600 μΩ-cm.

9. The phase change memory device as claimed in claim 1, wherein thickness of the seed layer is substantially 1 nm˜10 nm.

10. The phase change memory device as claimed in claim 1, wherein thickness of the conductive layer is substantially 10 nm˜100 nm.

11. A phase change memory device, comprising:
a first dielectric layer comprising an opening;
a seed layer and a conductive layer sequentially filled into the opening, wherein both the seed layer and the conductive layer are used as a bottom electrode of the phase change memory device;
a second dielectric layer fills a remaining portion of the opening; and
a top electrode couples the bottom electrode through a phase change layer, wherein the bottom electrode includes a barrier region and a conducting region, the barrier region is closer to the phase change layer than the conducting region, and resistance of the barrier region is higher than that of the conducting region.

12. The phase change memory device as claimed in claim 11, wherein the seed layer comprises Ti.

13. The phase change memory device as claimed in claim 11, wherein the conductive layer comprises Ta or TaN.

14. The phase change memory device as claimed in claim 11, resistance of the barrier region is more than twice that of the conducting region.

15. The phase change memory device as claimed in claim 11, wherein the barrier region of the bottom electrode comprises a TiN layer and a TaN layer, and the conducting region of the bottom electrode comprises a Ti layer and a Ta layer.

16. The phase change memory device as claimed in claim 11, wherein resistance of the conducting region of the bottom electrode is substantially less than 200 μΩ-cm.

17. The method for forming a phase change memory device as claimed in claim 11, wherein resistance of the barrier region of the bottom electrode is substantially more than 600 μΩ-cm.

18. The phase change memory device as claimed in claim 11, wherein thickness of the seed layer is substantially 1 nm˜10 nm.

19. The method for forming a phase change memory device as claimed in claim 11, wherein thickness of the conductive layer is substantially 10 nm˜100 nm.

20. A method for forming a phase change memory device, comprising:
providing a substrate;
forming a first dielectric layer on the substrate;
patterning the first dielectric layer to form an opening;
conformally depositing a seed layer on the first dielectric layer and into the opening;
conformally depositing a conductive layer on the seed layer;
blanketly depositing a second dielectric layer on the conductive layer;
recessing the second dielectric layer till the first dielectric layer, the seed layer and the conductive layer are exposed, wherein both the seed layer and the conductive layer are used as a bottom electrode of the phase change memory device;
forming a phase change layer on the second dielectric layer, the seed layer and the conductive layer; and
forming a top electrode on the phase change layer.

21. The method for forming a phase change memory device as claimed in claim 20, further comprising doping the bottom electrode to form a barrier region and a conducting region after recessing the second dielectric layer, wherein resistance of the barrier region is higher than that of the conducting region.

22. The method for forming a phase change memory device as claimed in claim 21, wherein doping the bottom electrode is accomplished by an ion implantation or thermal diffuse process.

23. The method for forming a phase change memory device as claimed in claim 21, wherein the step of doping the bottom electrode uses nitrogen as dopants.

24. The method for forming a phase change memory device as claimed in claim 20, wherein recessing the second dielectric layer is accomplished by chemical mechanical polishing CMP.
